(19) United States
(12) Patent Application Publication
(10) Pub. No.: US 2011/0179325 A1
(43) Pub. Date: Jul. 21, 2011

(54) SYSTEM FOR BOUNDARY SCAN REGISTER CHAIN COMPRESSION

(75) Inventors: Anuj Gupta, Delhi (IN); Himanshu Kukreja, Sonepat (IN)

(73) Assignee: FREESCALE SEMICONDUCTOR, INC, Austin, TX (US)

(21) Appl. No.: 12/687,893

(22) Filed: Jan. 15, 2010

(51) Int. Cl. G01R 31/3177; G06F 11/25

(52) U.S. Cl. 714/727; 714/E11.155

(57) ABSTRACT

A system for testing input/output pads of an integrated circuit includes boundary scan register chains, a test control unit and a test data processing unit. Input test data is provided to the test control unit, which then provides the test data to the test data processing unit. The test data processing unit processes the test data to obtain processed test data. Thereafter, the processed data is loaded in each of the boundary scan register chains in parallel. The processed test data is propagated sequentially through the plurality of boundary scan register chains to obtain output test data. The output test data is used to detect faults present in the input/output pads of the integrated circuit.

### BACKGROUND OF THE PRESENT INVENTION

The present invention relates generally to boundary scan of integrated circuits, and, more specifically, to boundary scan register (BSR) chain compression.

The circuit density of modern electronic systems has increased tremendously. Integrated circuits (ICs) that contained a few hundred transistors a few decades ago, now include millions of transistors. This increased circuit density has led to high-scale miniaturization in the size of electronic devices. However, such high scale miniaturization has made testing of electronic devices more difficult. Existing methods such as the ‘bed-of-nails’ test prove to be expensive for testing VLSI (Very Large Scale Integrated Circuits). Such methods fail when used for testing fine-pitch packages, multilayer Printed Circuit Boards (PCBs), and double-sided surface mounted boards.

In order to overcome the limitations of these test methods a device testing technique called boundary scan testing or Joint Test Action Group (JTAG) testing has been developed. The specification for the boundary scan testing architecture is detailed in the IEEE 1149.1 standard. A boundary scan testable device will be explained below in detail in conjunction with FIG. 1.

FIG. 1 is a schematic diagram illustrating a boundary scan testable IC 100, in accordance with IEEE 1149.1. The IC 100 includes a test control unit (TCU) 102, test input/output (I/O) pads 104a, 104b, 104c and 104d (referred to collectively as IC test I/O pads 104), IC I/O pads 104e and 104f (referred to collectively as IC I/O pads 104), and test ports 106a, 106b, 106c, and 106d (referred to collectively as test ports 106). The IC 100 further includes a core logic unit (not shown).

Each IC I/O pad 104 such as the IC I/O pad 104e is coupled to an adjoining pin of the IC 100 and to the core logic unit of the IC 100. The IC I/O pad 104e receives signals provided at the corresponding pin of the IC 100 and transmits the signal to the core logic unit. The test I/O pads 104a, 104b, 104c, and 104d are connected to the test ports 106a, 106b, 106c, and 106d respectively. Additionally, the I/O pads 104a, 104b, 104c, and 104d are connected to the TCU 102. The test port 106a is known as Test Data In (TDI) port, test port 106b is known as Test Data Out (TDO) port, test port 106c is known as Test Mode Select (TMS) port, and test port 106 d is known as Test Clock (TCK) port.

Each I/O pad 104 (the test I/O pads and the IC I/O pads) includes a Boundary Scan Cell (BSC) (not shown). The internal circuitry of the BSC is well known and is thus not explained in detail here. The BSCs of each of the I/O pads (except for the BSCs of the test I/O pads 104a, 104b, 104c, and 104d) are coupled to the BSCs of two adjacent I/O pads. The boundary scan input of the test I/O pads 104a-104d is grounded and the boundary scan output of the above-mentioned test I/O pads 104a-d is kept open. The connected BSCs may also be referred to as a Boundary Scan Register (BSR) chain. The BSCs of the IC I/O pads 104e-104f are coupled to a BSC of an adjacent I/O pad and to the TCU 102.

The input test data is provided at the pins of the IC 100. The input test data may be a test pattern for performing a JTAG test on the IC 100. In accordance with IEEE 1149.1, a JTAG compliant IC is capable of propagating test data sequentially through the various BSCs located in the I/O pads to check whether the I/O pads are functioning in a desired manner. During such a test the input test data traverses the BSR chain. Additionally, there are commands such as EXTEST, SAMPLE, PRELOAD, etc., specified by IEEE 1149.1, that enable testing of interconnects of a Printed Circuit Board (PCB).

In the above-described JTAG testing, the input test data is received by the test I/O pad 104a via the test port 106a and is provided to the TCU 102. The TCU 102, in addition to the test I/O pads 104a and 104b, is also connected to the test ports 106c and 106d through the I/O pads 104c and 104d respectively. As mentioned above, the test port 106c serves as a TMS port and test port 106d serves as a TCK port. The operational state of the BSR chain is controlled by the TCU 102 based on the signals received from the test ports 106a, 106c and 106d. In response to the above-mentioned signals, the TCU 102 generates control signals that enable various operations of the BSR chain. For example, when a ‘Capture’ operation of the BSR chain is initiated, signal values on the input pins of the IC 100 are loaded into the respective BSCs, and signal values passing from the core logic unit to the output pins are loaded into the BSCs associated with the output pins. Additionally, various other BSR operations such as the ‘Update’ and ‘Shift’ operations may be initiated by the control signals from the TCU 102. The TCU 102 is a finite state machine integrated on the IC 100 for controlling IEEE 1149.1 JTAG test-related operations of the IC 100 when the IC 100 is operating in a functional mode.

Subsequent to the receipt of the input test data by the TCU 102, the input test data is provided to the IC I/O pad 104e, which includes a first BSC of the BSR chain. Thereafter, the first BSC transmits the test data to a subsequent BSC located in an adjacent I/O pad. The transmittal of test data from the first BSC to the subsequent BSC is performed in accordance with a ‘Shift’ operation in which the test data is serially shifted from one BSC to the next BSC until it finally emerges at the TDO port. The above process continues until the input test data has traversed the entire BSR chain. The output test data emerges through the IC I/O pad 104f, which provides the output test data to the TCU 102. Thereafter, the TCU 102 provides the output test data to the test I/O pad 104b, which in turn transmits the output test data to a corresponding IC pin. After that, the output test data may be compared with reference output test data to determine whether there is a fault in the I/O pads.

In addition to the JTAG testing procedure described above, boundary scan testing is also performed on the IC 100. The boundary scan testing involves sequential test data shift operations similar to the JTAG test data shift operations described above. However, the operation of the BSR chain is not controlled by the TCU 102 while boundary scan testing is being performed.

The conventional scan based testing mentioned above may be used for testing the I/O pads. The scan based I/O pads testing involves a single BSR chain. The test data is then propagated sequentially through the BSR chain. After sequentially traversing the BSR, the test data emerges as output test data, which is later used to determine the faults present in the I/O pads. The above procedure of sequentially loading and shifting of the input test data in a single BSR chain consumes considerable time resulting in prolonged test times.

Further, it should be realized that several existing systems for testing for manufacturing faults in a semiconductor chip use various scan compression techniques. The scan compression techniques include Illinois scan, scan compression using Embedded Deterministic Testing (EDT™), Logic Built-in-Self-Test (LBIST), etc. Compressed test data, generated using Automatic Test Pattern Generation (ATPG) tools such as TestKompress®, Encounter® test, TetraMax®, etc., are stored in an Automatic Test Equipment (ATE) and is provided to an on-chip decompressor. The decompressor decompresses the test data and provides the decompressed test data to various scan chains. Thereafter, the output data obtained is provided to an on-board compactor. The compactor compresses the output data of the scan chains and provides compressed output data to the ATE for comparing the compressed output data with standard output data in order to detect on-chip faults. However, for I/O pad testing, uncompressed I/O BSR chain patterns need to be included along with the compressed test data. The generation of uncompressed patterns requires separate setup time and effort. Further, uncompressed ATPG patterns have a large pattern volume that further leads to additional overhead in loading the BSR chain and also increasing the overall scan test time.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 is a schematic diagram illustrating a conventional boundary scan testable IC 100 that complies with IEEE 1149.1;

FIG. 2A is a schematic diagram illustrating a boundary scan testable IC 200 in a scan mode in accordance with an embodiment of the present invention; and

FIG. 2B is a schematic diagram illustrating a boundary scan testable IC 200 in a JTAG mode in accordance with another embodiment of the present invention.

### DETAILED DESCRIPTION OF THE PRESENT INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In an embodiment of the present invention, a system for testing one or more input/output pads of an integrated circuit is provided. The input/output pads are coupled to a core logic unit of the integrated circuit. The system includes a plurality of boundary scan register chains in which each boundary scan register chain includes one or more boundary scan cells. Each of the boundary scan cells is associated with at least one input/output pad. The system further includes a test data processing unit that is coupled to the plurality of boundary scan register chains. The test data processing unit processes input test data and provides processed input test data to each of the plurality of boundary scan register chains in parallel. Further, the test data processing unit processes the output test data obtained from the plurality of boundary scan register chains. The system further includes a test control unit coupled to the test data processing unit for controlling operations of the plurality of boundary scan register chains.

Various embodiments of the present invention provide a system for testing input/output pads of an integrated circuit. The integrated circuit includes a plurality of boundary scan register chains, a test control unit and a test data processing unit. An input test data is provided to the test control unit, which then provides the test data to the test data processing unit. The test data processing unit processes the test data to obtain a processed test data. In an embodiment of the present invention, the input test data is uncompressed by the test data processing unit. The processed test data is then propagated sequentially through the plurality of boundary scan register chains to obtain an output test data. The output test data is thereafter compressed by the test data processing unit such that the compressed test data may be later used to determine faults in the input/output pads of the integrated circuit.

The implementation of compressed boundary scan register chains eliminates the need to generate uncompressed test patterns. This in turn results in reduction in test pattern generation time. Further, usage of compressed test patterns provides reduction in test data volume. Since, the volume of test data is reduced, the time required for loading the patterns is also reduced. Additionally, the parallel loading of the various boundary scan register chains results in less time for conducting a boundary scan test. The scan chain muxing unit in the TCU enables concatenation of the various BSR chains into a single BSR chain. This makes the proposed testing system compliant with IEEE 1149.1 and assists in execution of public JTAG commands such as EXTEST.

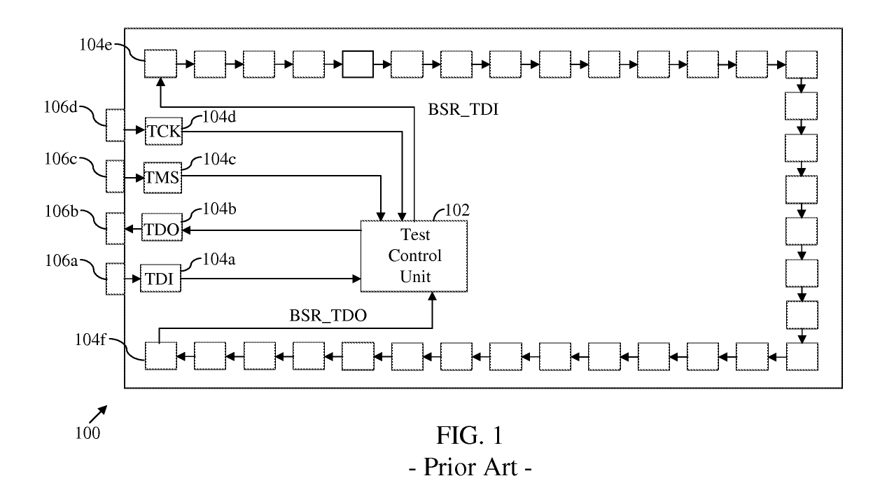

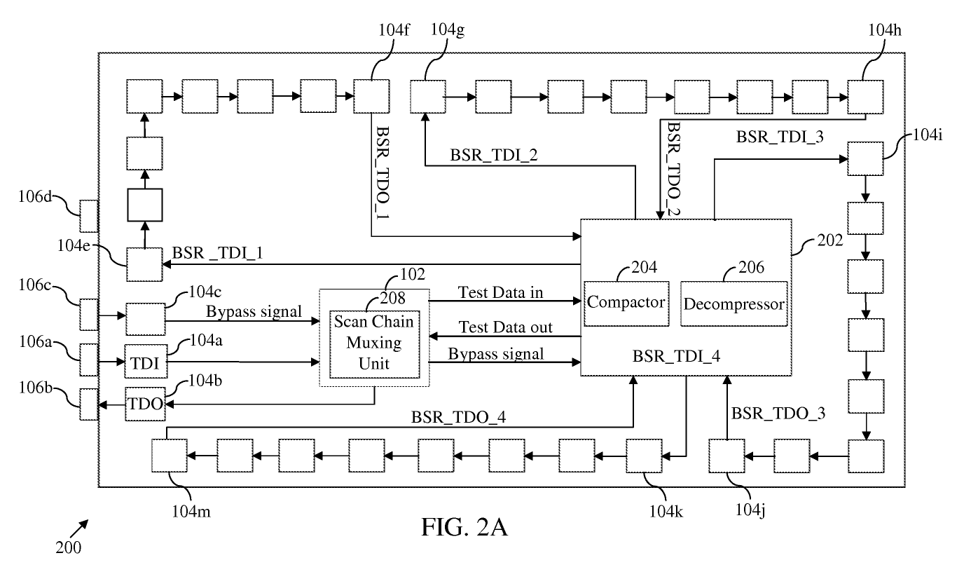

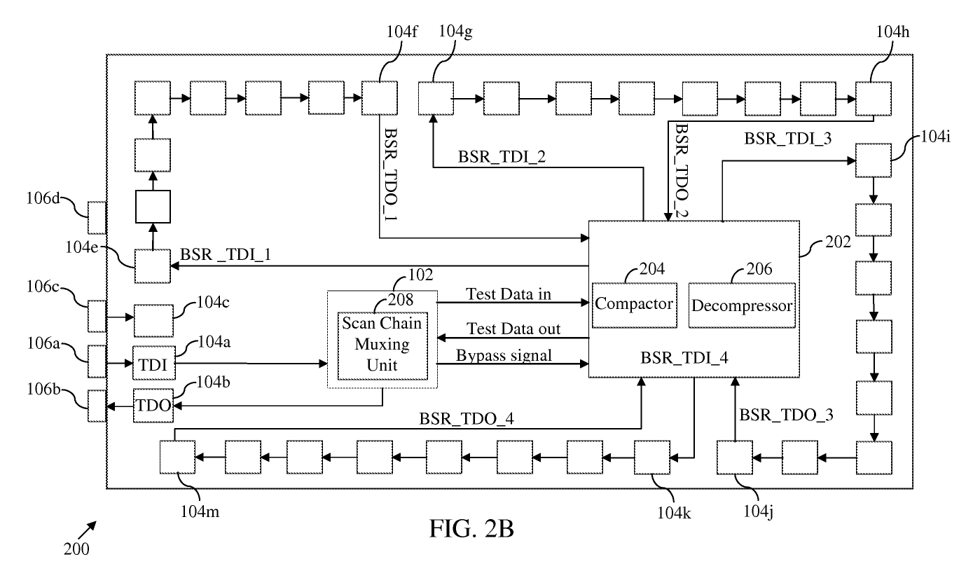

Referring now to FIG. 2A, a schematic block diagram illustrating a boundary scan testable IC 200 in a scan mode, in accordance with an embodiment of the present invention, is shown. In addition to elements described above as part of the IC 100 (FIG. 1), the IC 200 includes a test data processing unit 202. The test data processing unit 202 includes a compactor 204 and a decompressor 206. The test control unit 102 includes a scan chain muxing unit 208. Additionally, FIG. 2A depicts IC I/O pads 104e, 104f, 104g, 104h, 104i, 104j, 104k, and 104m. Further, it should be noted that the IC I/O pads 104e and 104f connected to the TCU 102 in FIG. 1, are connected to the test and data processing unit 202.

As shown in FIG. 2A, the single BSR chain of the IC 100 has been divided into more than one BSR chain. More particularly, in the embodiment of the present invention shown in FIG. 2A, the BSR chain of FIG. 1 is divided into four BSR chains. A first BSR chain extends from the IC I/O pad 104e to the I/O pad 104f. A second BSR chain extends from the IC I/O pad 104g to the IC I/O pad 104h, a third BSR chain extends from the IC I/O pad 104i to the IC I/O pad 104j, and a fourth BSR chain extends from the IC I/O pad 104k to the IC I/O pad 104m.

In a compressed scan mode of the IC 200, the test port 106c is used as a bypass port. Alternatively a bypass control signal can be generated by the TCU 102 based on the selected scan test mode, which eliminates the requirement for a separate I/O pad for the compression bypass signal. To enable operation of the IC 200 in the compressed scan mode, the bypass signal is kept low and the input test data is provided to the test I/O pad 104a through the test port 106a. The input test data includes compressed test patterns generated using known in the art ATPG tools such as TestKompress®, Encounter® test, TetraMax®, etc. The test I/O pad 104a transmits the input test data to the TCU 102. Thereafter, the TCU 102 transmits the input test data to the test data processing unit 202.

Embodiments of the present invention will now be explained based on a scenario in which the test data processing unit includes compressor and decompressor logic for EDT™ compression technique and input test data has been generated using the TestKompress® ATPG tool. The TCU 102 transmits the input test data to the test data processing unit 202. The test data processing unit 202 includes the compactor 204 and the decompressor 206. The decompressor 206 decompresses the compressed test patterns and provides the decompressed patterns to various BSR chains in parallel. Thereafter, the test patterns propagate sequentially through the various BSR chains and the output test data is provided to the compactor 204. The compactor 204 compresses the output test data and provides compacted test data to the TCU 102. The TCU 102 then provides the compacted test data to the ATE. The ATE then compares the compacted output test data with reference output test patterns to determined faults in the I/O pads.

Further, to enable an uncompressed scan mode of the IC 200, a bypass signal is provided to the TCU 102 via the test port 106c. The TCU 102 provides the bypass signal to the scan chain muxing unit 208. The scan chain muxing unit 208, in turn bypasses the EDT™ compression and decompression logic So that the four compressed BSR chains are concatenated to form a single BSR chain extending from the IC I/O pad 104e to the IC I/O pad 104m, thus enabling a conventional ATPG uncompressed scan mode.

Referring now to FIG. 2B, a schematic diagram illustrating a boundary scan testable IC 200 in a JTAG mode, in accordance with another embodiment of the present invention is shown.

It is known by persons skilled in the art that there are public instructions such as EXTEST specified by IEEE 1149.1, which enable testing interconnects of a PCB. To execute such public instructions, the BSR chains of various ICs present on the PCB must behave as a single concatenated chain. To achieve the above mentioned objective, the scan chain muxing unit 208 is integrated with the test data processing unit 202. The bypass signal is generated internally by the TCU 102 and is provided to the scan chain muxing unit 208. Thereafter, the scan chain muxing unit 208 bypasses the EDT™ compression and decompression logic to provide for concatenation of the BSR chains into a single BSR chain. Thus, the input test data provided to the IC I/O pad 104e propagates through the intermediate I/O pads to emerge at the IC I/O pad 104f and then is provided to the scan chain muxing unit 208 via the test data processing unit 202. Thereafter, output test data obtained from the first BSR chain is loaded into the second BSR chain, and so on. Thus, the various BSR chains behave as a single BSR chain that may be accessed from an IC pin. Further, the above described concatenation of the various compressed BSR chains ensures that the order of the I/O pads in the concatenated BSR chain is identical to the order of I/O pads defined in the Boundary Scan Descriptive Language (BSDL) file.

It should be understood by persons skilled in the art that the bypass logic for enabling chain concatenation may not be available in other scan chain compression solutions. In such a scenario, the bypass signal may not be required by the test data processing unit 202.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

What is claimed is:

1. An integrated circuit, comprising:
a plurality of input/output pads coupled to a core logic unit of the integrated circuit;
a plurality of boundary scan register chains, wherein each boundary scan register chain comprises a plurality of boundary scan cells, wherein each boundary scan cell is associated with at least one of the plurality of input/output pads;
a test data processing unit coupled to the plurality of boundary scan register chains, wherein the test data processing unit processes input test data and provides processed input test data to each of the plurality of boundary scan register chains in parallel, and wherein the test processing unit processes output test data obtained from the plurality of boundary scan register chains; and
a test control unit, coupled to the test data processing unit, for controlling operations of the plurality of boundary scan register chains.

2. The integrated circuit of claim 1, wherein the plurality of boundary scan register chains are concatenated to form a continuous boundary scan register chain.

3. The integrated circuit of claim 2, wherein an operation of the integrated circuit complies with Institution of Electrical and Electronics Engineers (IEEE) 1149.1 protocol and Joint Test Action Group (JTAG) protocol.

4. The integrated circuit of claim 1, wherein a first boundary scan cell and a last boundary scan cell of each boundary scan register chain are coupled to the test data processing unit.

5. The integrated circuit of claim 1, wherein when the integrated circuit is operating in JTAG mode, the test control unit generates a bypass signal for bypassing the test data processing unit.

6. The integrated circuit of claim 1, wherein when the integrated circuit is operating in a compressed scan mode, the integrated circuit receives a bypass signal generated external to the integrated circuit for bypassing the test data processing unit.

7. The integrated circuit of claim 1, wherein when the integrated circuit is operating in a compressed scan mode, a bypass signal for bypassing the test data processing unit is generated by the test control unit.

8. The integrated circuit of claim 1, wherein when the integrated circuit is operating in an uncompressed scan mode, a bypass signal for bypassing the test data processing unit is generated by a logic circuit external to the integrated circuit.

9. The integrated circuit of claim 1, wherein when the integrated circuit is operating in an uncompressed scan mode, a bypass signal for bypassing the test data processing unit is generated by the test control unit.

10. The integrated circuit of claim 1, wherein the test data processing unit processes the input and the output test data in accordance with at least one of a scan compression scheme, Illinois scan scheme, and a Logic Built-In Self Test (LBIST) scheme.

11. The integrated circuit of claim 1, wherein the input test data is generated using an Automatic Test Pattern Generation (ATPG) tool.

12. The integrated circuit of claim 9, wherein the ATPG tool includes at least one of TestKompress®, TetraMax®, and Encounter® Tests.

13. The integrated circuit of claim 1, wherein the test data processing unit comprises a decompressor for decompressing the input test data and a compactor for compressing the output test data,

14. The integrated circuit of claim 1, wherein the test control unit comprises a scan chain muxing unit for concatenating the plurality of boundary scan register scan chains.

15. The integrated circuit of claim 12, wherein the scan chain muxing unit is a multiplexer.
